(19) United States
(12) Patent Application Publication
(10) Pub. No.: US 2025/0299964 A1
(43) Pub. Date: Sep. 25, 2025

(54) PATTERN SHAPING OF METAL RESIST LAYER USING REACTIVE ANGLED BEAM PROCESSING

(71) Applicant: Applied Materials, Inc., Santa Clara, CA (US)

(72) Inventors: Yung-Chen LIN, Westwood, MA (US); Chih-An Hsu, Milpitas, CA (US); Huixiong DAI, San Jose, CA (US); Shurong LIANG, Lynnfield, MA (US); Steven SHERMAN, Newton, MA (US)

(73) Assignee: Applied Materials, Inc., Santa Clara, CA (US)

(21) Appl. No.: 18/815,094

(22) Filed: Aug. 26, 2024

Related U.S. Application Data
(60) Provisional application No. 63/567,773, filed on Mar. 20, 2024.

(51) Int. Cl. H01L 21/311; H01J 37/04; H01J 37/08; H01J 37/305

(52) U.S. Cl. CPC H01L 21/31116; H01J 37/045; H01J 37/08; H01J 37/3053; H01L 21/31144; H01J 2237/0435; H01J 2237/3174

(57) ABSTRACT

A method of enhancing patterning of a substrate. The method may include providing a metal resist mask on a substrate stack of the substrate, wherein the metal resist mask comprises at least one patterning feature. The method may include subjecting the metal resist mask to a directional etch, by directing an angled ion beam to the at least one patterning feature. The angled ion beam may comprise reactive species to etch the at least one patterning feature by forming volatile etch products, wherein a first dimension of the at least patterning feature is selectively altered with respect to a second dimension of the at least one patterning feature.

### RELATED APPLICATIONS

This application claims priority to U.S. provisional patent application Ser. No. 63/567,773, filed Mar. 20, 2024, entitled PATTERN SHAPING OF METAL RESIST LAYER USING REACTIVE ANGLED BEAM PROCESSING, the contents of which application are incorporated herein in their entirety.

### FIELD

The present embodiments relate to semiconductor device processing techniques, and more particularly, to processing for mask layer patterning.

### BACKGROUND

As semiconductor devices continue to scale to smaller dimensions, the ability to pattern features becomes increasingly difficult. These difficulties include, in one aspect, the ability to obtain features at a target size for a given technology generation. Another difficulty is the ability to obtain the correct shape of a patterned feature, as well as packing density, and the ability to obtain correct overlay to structures patterned in previous processing operations.

In another example, lithographic patterning of arrays of features, such as lines, trenches, or holes, becomes increasing difficult as overall spacing (pitch) between adjacent features becomes smaller. In particular, in arrays of patterned features, reducing the so-called tip-to-tip spacing between adjacent features along a long direction becomes especially difficult using known lithographic approaches, as the designed spacing becomes smaller along the short direction of such features. This problem becomes especially acute as overall pitch shrinks below 50 nm. Moreover, as the designed pitch for devices, such as CMOS, other logic devices, DRAM, and so forth, reduces below 30 nm, traditional photoresist materials that are used to define a pattern within a mask layer, may be less effective for patterning using current-day lithographic technology, such as EUV. As such, in addition to improvements in patterning techniques for small pitches, new materials are called for to pattern arrays of structures in a resist layer as the pitch of such structures decreases.

With respect to these and other considerations, the present improvements may be useful.

### BRIEF SUMMARY

In one embodiment, a method of enhancing patterning of a substrate is provided. The method may include providing a metal resist mask on a substrate stack of the substrate, wherein the metal resist mask comprises at least one patterning feature. The method may include subjecting the metal resist mask to a directional etch, by directing an angled ion beam to the at least one patterning feature. The angled ion beam may comprise reactive species to etch the at least one patterning feature by forming volatile etch products, wherein a first dimension of the at least patterning feature is selectively altered with respect to a second dimension of the at least one patterning feature.

In another embodiment, an apparatus to etch a substrate having a metal mask is provided. The apparatus may include a plasma chamber to generate a plasma therein, a process chamber, adjacent to the plasma chamber, to house the substrate, and an extraction plate, disposed between the plasma chamber and the substrate, and having an extraction aperture to generate and direct an angled ion beam to the substrate. The apparatus may also include a gas source, to provide a gas mixture to the plasma chamber to form the plasma, wherein the gas mixture includes at least one hydrogen-containing gas, at least one carbon-containing gas, and at least one inert gas, and wherein the at least one hydrogen-containing gas comprises at least one of: include CH₄, CₓH_{y}, CₓH_{y}OH, HCl, and HBr.

In a further embodiment, a method of enhancing patterning of a substrate may include providing a SnO₂ resist mask on a substrate stack of the substrate, wherein the SnO₂ mask comprises at least one patterning feature, and forming a plasma in a plasma chamber using a gas mixture comprising an inert gas and at least one of: CH₄, CₓH_{y}, CₓH_{y}OH, HCl, and HBr. The method may further include extracting an angled ion beam from the plasma chamber and directing the angled ion beam to the at least one patterning feature, wherein the angled ion beam comprises reactive species to etch the at least one patterning feature by forming volatile etch products. As such, a first dimension of the at least one patterning feature may be selectively altered with respect to second dimension, and a protective layer formed on a top surface of the at least one patterning feature.

### BRIEF DESCRIPTION OF THE DRAWINGS

FIG. 1A depicts a side cross-sectional view of processing of a device structure, using an angled ion beam, according to various embodiments of the disclosure;

FIG. 1B depicts a top plan view of the processing operation depicted in FIG. 1A;

FIG. 1C depicts details of a variant of the processing scenario of FIG. 1A;

FIG. 2A depicts a side cross-sectional view of processing of another device structure, using an angled ion beam, according to various embodiments of the disclosure;

FIG. 2B depicts a top plan view of the processing operation depicted in FIG. 2A;

FIG. 3A depicts a top plan view of processing a further device structure using angled ion beam etching, according to further embodiments of the disclosure;

FIG. 3B depicts a top plan view of the device structure of FIG. 3A after the operation of FIG. 3A;

FIG. 4A depicts a top plan view of processing an additional device structure using angled ion beam etching, according to further embodiments of the disclosure;

FIG. 4B depicts a top plan view of the device structure of FIG. 4A after the operation of FIG. 4A;

FIG. 5A depicts a top plan view of processing yet another device structure using angled ion beam etching, according to further embodiments of the disclosure;

FIG. 5B depicts a top plan view of the device structure of FIG. 5A after the operation of FIG. 5A;

FIG. 5C depicts a top plan view of processing yet another device structure using angled ion beam etching, according to further embodiments of the disclosure;

FIG. 5D depicts a top plan view of the device structure of FIG. 5C after the operation of FIG. 5C;

FIG. 6A shows a block view of another processing apparatus according to further embodiments of the disclosure;

FIG. 6B illustrates a top plan view of an extraction geometry of the processing apparatus of FIG. 6A, according to further embodiments of the disclosure;

FIG. 6C shows a block view of another processing apparatus according to further embodiments of the disclosure;

FIG. 7 is a composite illustration including experimental micrographic images of processing an array of patterning features, in accordance with embodiments of the disclosure;

FIG. 8 is a composite illustration including experimental micrographic images of processing another array of patterning features, in accordance with embodiments of the disclosure;

FIG. 9A is a composite illustration including experimental micrographic images of processing a further array of patterning features, showing a comparison of results when angled ion beam etching is omitted after lithography, or is used after lithography, in accordance with embodiments of the disclosure;

FIG. 9B and FIG. 9C are side cross-sectional views that depict the general geometry at two different stages of processing of patterning features, applicable to the scenario for processing of FIG. 9A;

FIG. 10 depicts an exemplary process flow;

FIG. 11 depicts another exemplary process flow;

FIG. 12 depicts a further exemplary process flow; and

FIG. 13 depicts yet another exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

The present embodiments provide novel techniques to pattern substrates and in particular novel techniques to etch a patterning feature or an array of patterning features that are disposed on a substrate. As used herein the term “substrate” may refer to an entity such as a semiconductor wafer, insulating wafer, ceramic, as well as any layers or structures disposed thereon. As such, a surface feature, layer, series of layers, or other entity may be deemed to be disposed on a substrate, where the substrate may represent a combination of structures, such as a silicon wafer, oxide layer, and so forth.

In various embodiments, the patterning feature may be disposed in a patterning layer, such as a photoresist layer (referred to herein also as a “resist layer”), and in particular a metal resist layer. Examples of a metal resist layer include metallic oxides such as SnO₂ or similar metal oxides. Examples of a patterning feature include a cavity formed within a layer, such as a via, or trench. In other examples, a patterning feature may be a pillar, a line structure (line), or other feature extending above a substrate. Moreover, the term “layer” as used herein may refer to a continuous layer, a semicontinuous layer having blanket regions and regions of isolated features, or a group of isolated features generally composed of the same material and disposed on a common layer or substrate.

In various embodiments, ion beam etching techniques are provided to modify a patterning feature or array of patterning features after lithographic processing is performed on a patterning layer in order to form the patterning feature(s). This post-lithography processing may overcome shortfalls of known lithography, especially at the nanometer scale, such as for features having minimum dimensions in the range of 2 nm to 100 nm.

By way of reference, new resist materials, such as metal resists are contemplated for lithographic patterning of features as the dimension of such features continues to shrink. As an example, for arrays of features where the pitch of such arrays reduces below approximately 40 nm, metal resists may provide advantages over present day resist materials. Such metal resists, including SnO₂, may be suitable for patterning using extreme ultraviolet (EUV) lithography. However, lithographic patterning of photoresists, whether metal resist or otherwise, may still be unable to suitable define small features, such as obtaining small tip-to-tip separation between adjacent features.

The present embodiments address this issue and other patterning issues by providing a novel angled ion beam processing approach that is suitable to selectively modify the dimensions of key aspects of a patterned metal resist layer. The novel angled ion beam approach may include novel gas chemistries and directional pattern shaping of a patterned metal resist layer so that the dimensions of patterning features are modified in manner that is not achievable by the use of EUV lithography alone to define such patterning features.

As detailed below, the pattern shaping of a metal resist layer may be performed directly after metal resist EUV patterning, easier for the re-work process. The present approach may avoid the need to use an extra EUV mask that would otherwise be necessary, and may increase device density and/or improve device performance. In particular embodiments, the novel gas chemistry used to generate an angled ion beam may mitigate metal contamination issues that arise from processing metal resist layers, such as during etching of such layers.

In various embodiments of the disclosure, methods for enhancing patterning of a substrate are provided. The angled ion beam etching approach as disclosed herein may be thought of as an adjunct to lithographic patterning a mask layer, such as a metal resist mask. In various embodiments the method involves providing a metal resist mask on a substrate stack of the substrate, where the metal resist mask comprises at least one patterning feature, such as an array of patterning features. The metal resist mask is then subjected to a directional etch that is performed by directing an angled ion beam to the patterning feature(s). As such, the angled ion beam may include reactive species to etch the patterning feature(s) by forming volatile etch products, wherein the dimensions of the patterning feature(s) are selectively altered. As an example, a first dimension of a patterning feature that extends along a first direction may be selectively altered with respect to a second dimension, after the directional etch is performed. In particular examples, a linewidth of a metal line may be reduced by a given amount, while a line length of the meal line is unaffected, or is reduced to a lesser extent as compared to the reduction in linewidth. In another example, a trench length of a trench may be selectively increased by a given amount, while a trench width of the trench is unaffected or is changed by a lesser amount as a result of the directional etch. As a result of the directional etch, the pattern shaping of a metal resist mask pattern may be tailored according to a targeted device requirement, for example.

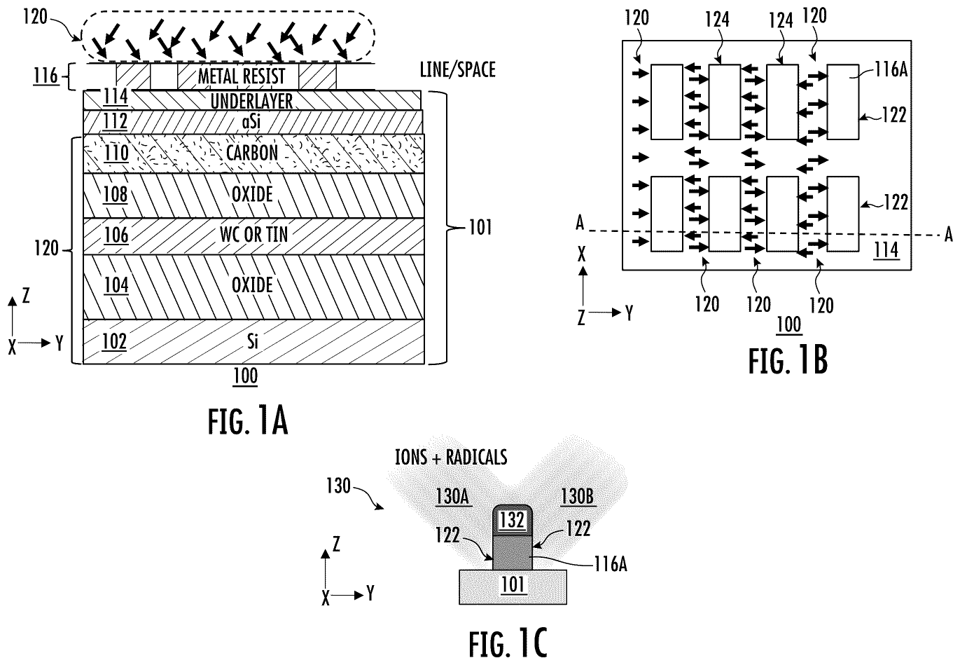

Turning to FIG. 1A there is shown a side cross-sectional view of a processing of a device structure, using an angled ion beam, according to various embodiments of the disclosure. FIG. 1B depicts a top plan view of the processing operation depicted in FIG. 1A.

The device structure 100 may be formed in or on a substrate 102, such as a semiconductor wafer, such as silicon, where a device stack 101 is shown, with a metal resist layer 116 disposed above the device stack 101, in order to pattern one or more layers within the device stack 101. Merely for the purposes of illustration, the device stack 101 is shown to include a sub-stack 121, which sub-stack is representative of a back-end-of-line stack for line-space patterning. Included in the sub-stack 121 is an oxide layer 104, metal layer 106, such as WC or TiN, second oxide layer 108 and carbon layer 110. In this embodiment, disposed above the sub-stack 121 is an interface layer 114 and silicon underlayer 112, which layer may be formed of amorphous silicon, silicon carbide, or Silicon-boron.

In the scenario of FIG. 1A, the metal resist layer 116 acts as a patterning layer, as noted. The metal resist layer 116 may include a metal feature, such as a metal line, or a cavity formed within a metal layer. In the particular embodiment depicted in FIG. 1A, the metal resist layer 116 includes a plurality of metal features, which features may be termed metal lines, more completely depicted in FIG. 1B. In particular, the plurality of metal features may be termed an array of patterning features, and may be defined according to a targeted linewidth, line length, or pitch (distance between centers adjacent patterning features along a given direction, such as the X-direction or Y-direction in the Cartesian coordinate system shown). The exact shape and dimensions of the features of metal resist layer 116 may initially be defined immediately after lithographic patterning of the metal resist layer 116.

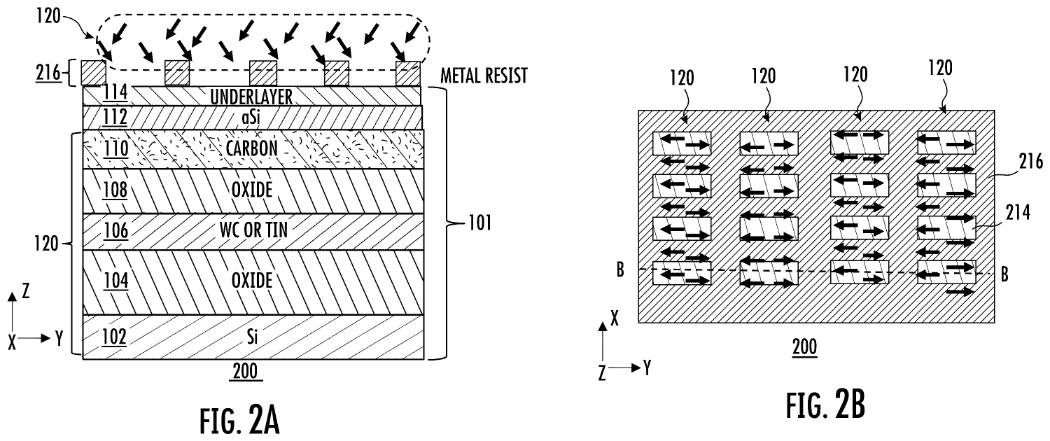

In the scenario of FIG. 1A and FIG. 1B, the metal resist layer 116 is subject to a directional ion beam etching using an angled ion beam 120. The metal resist layer 116 may be said to extend along a main plane of the substrate 102, meaning along the X-Y plane. As such, the angled ion beam 120 may define a trajectory that is arranged at a non-zero angle with respect to a perpendicular (in this case, the Z-axis) to the main plane (X-Y) plane. Moreover, as shown in FIG. 1B, the trajectory of ions of the angled ion beam 120 (as represented by the arrows), as projected on the main plane (X-Y plane) may extend along a defined direction in the X-Y plane, such as along the Y direction, where the lines 116A are arranged such that the angled ion beam 120 strikes sidewalls 122, but does not strike endwalls 124. In this manner, the lines 116A may be selectively etched just along the Y-direction. In this embodiment, and embodiments of FIGS. 2A, 3A, 4A, and 5A to follow, the angled ion beam 120 may be composed of two beamlets that define opposite angles of incidence as shown.

In some embodiments, the metal resist layer 116 may form a mask that includes the material SnO₂. As known, SnO₂ metal mask layers are suitable for processing using EUV lithography. Thus, the metal resist mask layer 116 may represent a patterned SnO₂ metal mask, just after lithographic patterning, in some embodiments. Note that the metal resist mask layer 116 may be initially formed from an known resist material, such as an Sn—OH—R material (where R represents a suitable C—H ligand). After EUV exposure during EUV lithography, the SnO₂ mask layer may be characterized by a Sn—O—Sn matrix, with some additional C—H and/or O—H material. In accordance with embodiments of the disclosure, the angled ion beam 120 may be formed from a set of species that are generated in a plasma chamber, where the set of species includes at least one inert gas, and further includes at least one hydrogen-containing gas.

As detailed further below, the present inventors have found certain gas chemistries that are suitable for directional ion beam etching of patterned metal resist features, such as metal resist features formed in a SnO₂ metal mask. In brief, the set of species have been found suitable for ion beam etching of an SnO₂ metal mask in a manner that generates volatile etch products including metallic species that contain Sn. Thus, the ion beam etching process as generally depicted in FIG. 1A and FIG. 1B may avoid metal contamination that may otherwise arise when etching a metal resist in a manner where metal species are not volatilized and redeposit on a substrate surface, substrate back side, substrate holder, or processing chamber holding the substrate, for example. In particular embodiments, the set of species provided to a plasma chamber that generates the angled ion beam 120 include at least one inert gas, and further include at least one hydrogen-containing gas. In some additional embodiments, besides inert gas and hydrogen species, the set of species may include carbon-containing species. The inert gas may include He, Ar, Xe or a combination, thereof, for example. Non-limiting examples of suitable hydrogen-containing gas and/or carbon-containing gas may include CH₄, CₓH_{y}, CₓH_{y}OH, HCl, and HBr.

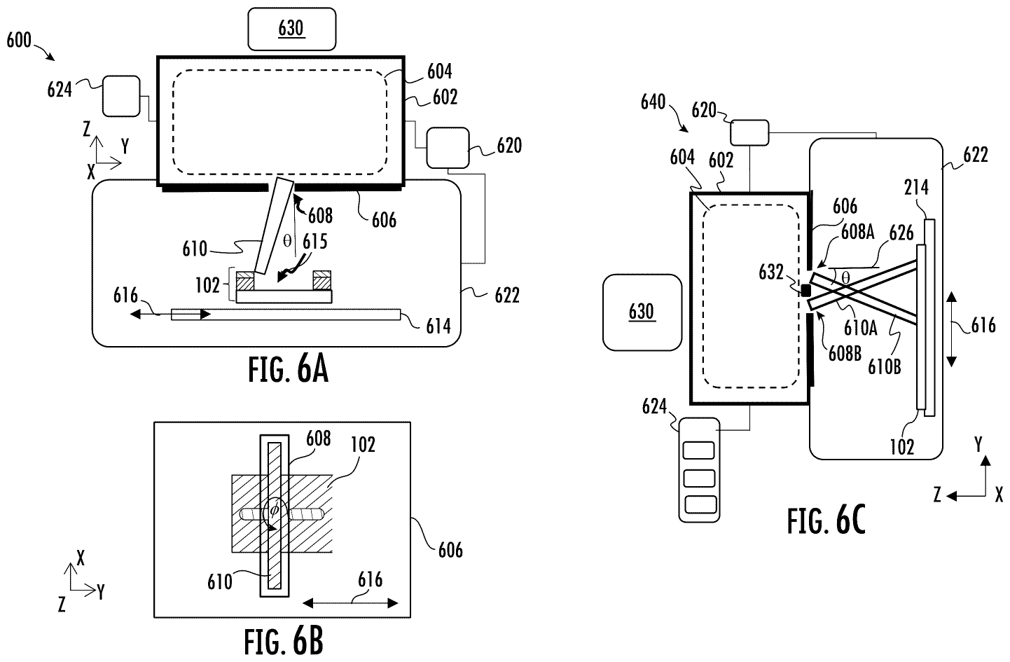

According to various embodiments of the disclosure, the angled ion beam 120 may include a combination of ions and radicals. In a given plasma chamber (not separately shown, but see FIGS. 6A-6C, discussed below), inert gas may be ionized into inert ions, such as Ar⁺, while a hydrogen-containing gas may be ionized to generate species such as H⁺. Such ion species will provide a high degree of directionality to angled ion beam 120, since those ion species will be subject to electric fields as set by various components of an ion beam processing apparatus. In addition, hydrogen radicals may be produced and form part of the angled ion beam 120. Such radicals, whether ionized or not, may react with elements in the resist mask layer 116, such as Sn, to form a volatile metal-containing etch product, such as SnH₄. Such a volatile metal-containing etch product may then be pumped away be a pumping system used to evacuate the ambient surrounding the substrate 102, thus avoiding metal by-product redeposition on substrate 102 or a chamber containing the substrate 102.

In particular embodiments, during the etching process using angled ion beam 120, carbon species or CHₓ radicals may form, and may tend to more readily deposit on top surfaces of the resist mask layer 116. In this manner, a carbon-containing deposit, such as a hydrocarbon layer, such as a polymer layer, may tend to form on the upper surface of the resist mask layer 116, so as to provide an etch resistant surface that reduces the erosion of the resist mask layer 116 along the Z-direction, thus preserving the thickness of the resist mask layer 116. As such, the angled ion beam etching process of FIG. 1A and FIG. 1B may selectively etch the resist mask layer just along the Y-direction, while not etching or etching to a lesser extent along the X-direction and along the Y-direction. Moreover, the chemistry of the angled ion beam 120 may be designed so as to selectively etch the resist mask layer 116 along the Y-direction, while not etching the interface layer 114 or silicon underlayer 112. Non-limiting examples of a suitable ion energy for angled ion beam 120 include 0.5 keV to 3 keV.

FIG. 1C depicts details of a variant of the processing scenario of FIG. 1A. In this example, a metal line 116A is subject to an angled ion beam 130 that is formed of two angled ion beamlets, such as beamlets 130A, and beamlet 130B, which beamlets are directed at opposite non-zero angles with respect to the X-Z plane. In this manner, the beamlets 130A may strike the metal line 116A on opposite ones of sidewalls 122, and thus etch the metal line 116A along the Y-axis in opposing directions.

FIG. 2A depicts a side cross-sectional view of processing of another device structure, using an angled ion beam, according to various embodiments of the disclosure. FIG. 2B depicts a top plan view of the processing operation depicted in FIG. 2A. In this example, the same general features of the angled ion beam 120 as discussed above with respect to FIGS. 1A and FIG. 1B may apply. Similarly, the device structure 200 may include the device stack 101. A difference is that a metal resist mask layer 216 is provided to pattern the subjacent substrate layers. The metal resist mask layer 216 includes an array of isolated cavities, shown as cavities 214, which cavities may be illustrated as an array of rectangular trenches for the sake of explanation. Again, the angled ion beam 120 may be provided in a manner to selectively etch the cavities 214 along the Y-direction, while not etching the cavities along the X-direction, or etching to a lesser extent along the X-direction. Likewise, the thickness of the metal resist mask layer 216 may be preserved during the exposure to angled ion beam 120, for the same reasons as discussed above with respect to FIG. 1A and FIG. 1B. Note also that the angled ion beam 120 is provided as a pair of beamlets having trajectories whose projections align along the Y-axis as viewed in the top plan view of FIG. 2B. However, the projection of the trajectories of ions of the two different beamlets (see also FIG. 6C) show that the ions travel in opposite directions with respect to the X-Z plane, as viewed in FIG. 2B and therefore will tend to strike opposite sides of the cavities 214. However, in additional embodiments of the disclosure, a single ion beam may be used to process a metal resist mask layer 216, where the trajectories of the single ion beam all face the same direction, and thus strike a single side of a mask feature.

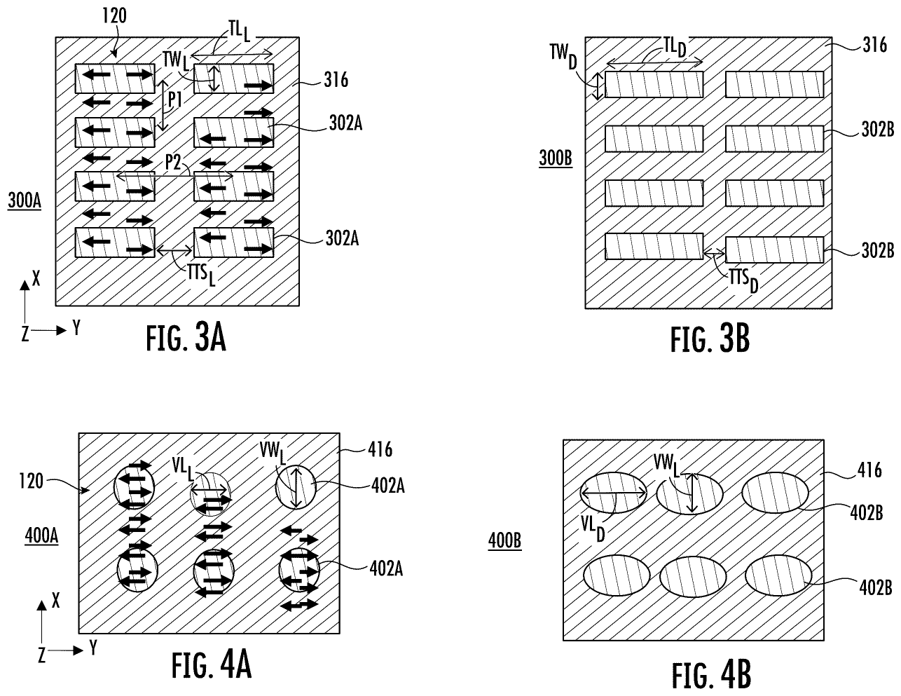

To illustrate the results of the aforementioned angled ion beam processing FIGS. 3A-5B depict ‘before’ and ‘after’ snapshots of exemplary metal resist mask layers that are subject to angled ion beam processing for different pattern types in a given metal resist mask layer.

FIG. 3A depicts a top plan view of processing a further device structure using angled ion beam etching, according to further embodiments of the disclosure. FIG. 3B depicts a top plan view of the device structure of FIG. 3A after the operation of FIG. 3A. In FIG. 3A, the angled ion beam 120 is used to process a metal resist mask layer 316 formed on a top surface of the device structure 300A, which structure includes an array of trenches, shown as trenches 302A. The metal resist mask layer 316 may be similar to metal resist mask layer 216, and may include trenches 302A that are arranged in a regular array, where the trenches 302A are initially defined by lithographic processing of the metal resist mask layer 316 to have a certain width along the X-direction, a certain length along the Y-direction, and a designated pitch along both of these directions, shown as P1 and P2. As such, the metal resist mask layer in device structure 300A may be characterized by trenches 302A having a trench width (along the X-direction) that is formed immediately after lithographic processing is performed, shown as TWL, and additionally having a trench length (along the Y-direction) that is formed immediately after lithographic processing is performed, shown as TL_{L}.

As shown in FIG. 3B, after the exposure to angled ion beam 120, the trenches 302B of device structure 300B (representing the device structure 300A after etching of the metal resist mask layer 316) may exhibit is trench shape where the length of the trench is increased, to a trench length characterized by TL_{D}. The latter trench length, meaning TL_{D}, may be representative of a designed trench length for the device structures to be formed in the underlying substrate. In a related issue, the trenches 302A, as a result of forming in a regular array, characterized by a P1 and P2, will exhibit an initial tip-to-tip spacing immediately after lithographic processing, shown as TTS_{L}. Note that the value of this parameter is an inherent result of the values pitch P2 and TL_{L} where TTS_{L}=P2−TL_{L}.

Note that the value of TTS_{L} may be larger than a design value for the tip-to tip spacing for the device to be formed from device structure 300A. The fact that TTS_{L} may be larger than a targeted value may be an inherent result of the lithographic process used to define the array of the trenches 302A. This result may be especially pertinent to mask layer patterns that are characterized by arrays of features that are formed using lithographic processing of a resist mask layer, when the pitch P1 is less than 40 nm. In order to reach the designed tip-to-tip spacing, the length of trenches 302A needs to increased along the Y-direction, which effect may be accomplished using the angled ion beam 120, according to the principles discussed above, with respect to FIGS. 1A-2B. As shown in FIG. 3B, in one example, after processing using the angled ion beam 120, the resulting structure of the array of trenches 302B, yielding the increased trench length, meaning TLD, may then produce the design value of tip-to-tip spacing, shown as TTSD.

Moreover, as a result of the geometry of the angled ion beam 120, etching of the trenches 302A may be minimal or non-existent along the X-direction, such that the width of the trenches 302A is not altered as a result of the exposure to angled ion beam 120. In other words, the value of TWL for trenches 302A may be the same as the value of the trench width of trenches 302B after exposure to angled ion beam 120. In FIG. 3B, the value of the trench width of trenches 302B is shown as TWD meaning that this width may correspond to the designed with for trenches to be formed in the device structure 300B.

FIG. 4A depicts a top plan view of processing an additional device structure using angled ion beam etching, according to further embodiments of the disclosure. FIG. 4B depicts a top plan view of the device structure of FIG. 4A after the operation of FIG. 4A. In this case, a device structure 400A is shown, representing a metal resist mask layer 416 that is disposed on a substrate stack to be patterned.

The metal resist mask layer 416 may include cavities for use as contact vias or other vias, and are shaped as vias 402A that are arranged in a regular array, where the vias 402A are initially defined by lithographic processing of the metal resist mask layer 416 to have a certain width along the X-direction (not shown in this case), a certain length along the Y-direction that is formed immediately after lithographic processing is performed, shown as VL_{L}. In some examples, a design shape for the vias 402A may differ from the shape of the vias 402A, as actually produced immediately after lithography. For example, the design shape of the vias 402A may be an elongated oval shape along the Y-direction, different from the more circular shape of vias 402A. After the processing using angled ion beam 120A, the final shape of features in metal resist mask layer 416, shown in device structure 400B, may be such an elongated oval structure, as exhibited by elongated vias 402B, having a length VL_{D}, which length may represent the design length for such vias. Moreover, as a result of the high degree of directionality of etching that is afforded by the angled ion beam 120, the original width of vias 402A immediately after lithographic processing, shown as VL_{D}, may be preserved in vias 402B.

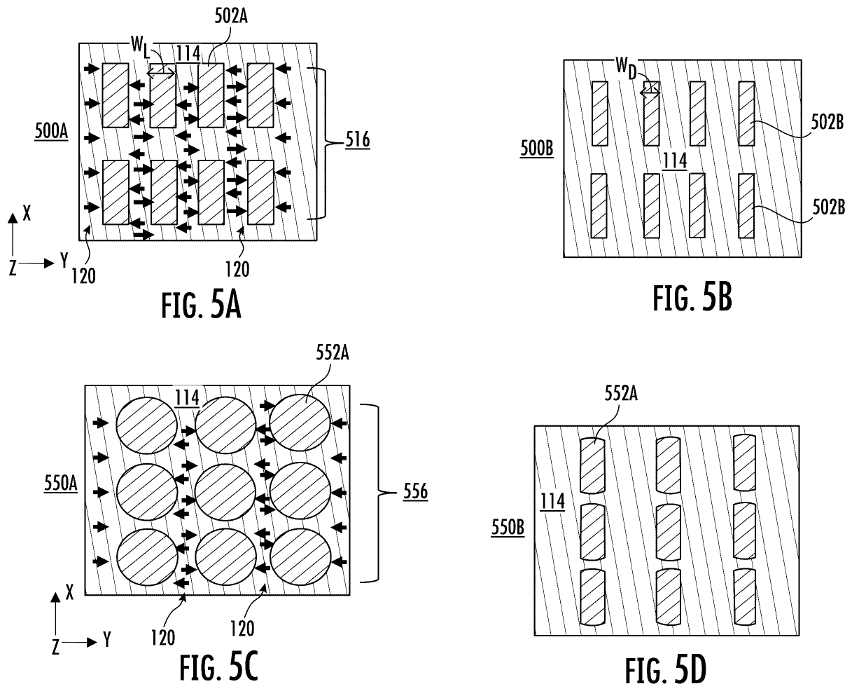

FIG. 5A depicts a top plan view of processing yet another device structure using angled ion beam etching, according to further embodiments of the disclosure. FIG. 5B depicts a top plan view of the device structure of FIG. 5A after the operation of FIG. 5A.

The device structure 500A is characterized by a metal resist mask layer. The metal resist mask layer 516 that may be similar to metal resist mask layer 116, and may include an array of lines, shown as lines 502A, which lines are selectively etched by the angled ion beam 120 just along the Y-direction. As such, after etching, the device structure 500B in FIG. 5B, exhibits a decreased linewidth, where the initial linewidth of lines 502A, immediately after lithography, shown as W_{L}, is reduced to a final linewidth, shown as W_{D} Moreover, as a result of the geometry of the angled ion beam 120, etching of the lines 502A along the X-direction may be minimal or non-existent, such that the length of the lines 502A is not altered as a result of the exposure to angled ion beam 120. In other words, the value of L_{L} for lines 502A may be the same as the value of the line length of lines 502B after exposure to angled ion beam 120.

FIG. 5C depicts a top plan view of processing yet another device structure using angled ion beam etching, according to further embodiments of the disclosure. FIG. 5D depicts a top plan view of the device structure of FIG. 5C after the operation of FIG. 5C. The device structure 550A is characterized by a metal resist mask layer. The metal resist mask layer 556 an array of pillars, shown as pillars 552A, which pillars are selectively etched by the angled ion beam 120 just along the Y-direction. As such, after etching, the pillars 552B of device structure 550B in FIG. 5D, exhibit a decreased width along the Y-direction. Moreover, as a result of the geometry of the angled ion beam 120, etching of the pillars 552A along the X-direction may be minimal or non-existent, such that the length or diameter of the pillars 552A is not altered as a result of the exposure to angled ion beam 120. As a result, the shape of the pillars 552A is altered after angled ion beam etching from a circular shape to an elongated shape, as shown in FIG. 5D.

Turning now to FIG. 6A, there is shown a processing apparatus 600, depicted in schematic form. The processing apparatus 600 represents a processing apparatus for selectively etching portions of a substrate, such as selectively elongating a cavity or shaping a line or pillar. The processing apparatus 600 may be a plasma-based processing system having a plasma chamber 602 for generating a plasma 604 therein by any convenient method as known in the art. A power supply 630, may, for example, be an RF power supply to generate the plasma 604. An extraction plate 606 may be provided as shown, having an extraction aperture 608, where a selective etching may be performed to selectively remove sidewall layers. A substrate, such as a substrate 102 having a suitable structure, such any of the aforementioned device structures as shown at FIG. 1A to FIG. 5B, is disposed in the process chamber 622. A substrate plane of the substrate 102 is represented by the X-Y plane of the Cartesian coordinate system shown, while a perpendicular to the plane of the substrate 102 lies along the Z-axis (Z-direction).

During a directional etching operation, an angled ion beam 610 is extracted through the extraction aperture 608 as shown. In one embodiment, the angled ion beam 610 may represent angled reactive ion beam, such as angled ion beam 120, described above. The angled ion beam 610 may be extracted when a voltage difference is applied using bias supply 620 between the plasma chamber 602 and substrate 102 as in known systems. The bias supply 620 may be coupled to the process chamber 622, for example, where the process chamber 622 and substrate 102 are held at the same potential. In various embodiments, the angled ion beam 610 may be extracted as a continuous beam or as a pulsed ion beam as in known systems. For example, the bias supply 620 may be configured to supply a voltage difference between plasma chamber 602 and process chamber 622, as a pulsed DC voltage, where the voltage, pulse frequency, and duty cycle of the pulsed voltage may be independently adjusted from one another.

By scanning a substrate stage 614 including substrate 102 with respect to the extraction aperture 608, and thus with respect to the angled ion beam 610, along the scan direction 616, the angled ion beam 610 may etch targeted surfaces of structures, such as metal resist mask features 615, which features may be lines, trenches, vias, pillars, or other structures. In particular, the surfaces of such structures may be oriented so as to promote etching along targeted surfaces, such as sidewalls, and to disfavor etching along other surfaces, such as endwalls. In particular, surfaces that are oriented perpendicularly to the scan direction 616 may be selectively etched, as suggested in FIG. 6B. In various embodiments, for example, the extraction aperture 608 may be provided as an elongated aperture, elongated along the X-direction, such that the angled ion beam 610 is provided as a ribbon ion beam having a long axis that extends along the X-direction of the Cartesian coordinate system shown in FIG. 6B. The substrate 102 may be arranged, for example, where a set of set of walls to be etched lies along the X-axis, while another set of walls not to be etched, lies along the Y-axis. In this manner, as shown in FIG. 6A, the angled ion beam 610, forming a non-zero angle of incidence with respect to the Z-axis (normal to the substrate plane), may strike the sidewalls oriented along the X-Z plane, as noted. This geometry facilitates reactive ion etching of the X-Z sidewalls, while not etching the Y-Z sidewalls, and thus selectively changes a first dimension of a patterning feature along a first direction, of a metal resist mask layer, while not changing a second dimension of the patterning feature along a second direction, perpendicular to the first direction, or changing the second dimension to a lesser extent. In various embodiments, the value of the non-zero angle of incidence may vary from 10 degrees to 75 degrees, while in some embodiments the value may range between 15 degrees and 60 degrees, or between 20 degrees and 45 degrees. The embodiments are not limited in this context. The angled ion beam 610 may be composed of any convenient gas mixture, including inert gas, reactive gas, and may be provided in conjunction with other gaseous species in some embodiments. Gas may be provided from a gas source 624, where the gas source 624 may be a gas manifold coupled to provide a plurality of different gases to the plasma chamber 602. In particular embodiments, the angled ion beam 610 and other reactive species may be provided as an etch recipe to the substrate 102 so as to perform a directed reactive ion etching of targeted sidewalls of patterning layers on substrate 102. As discussed above, the etch recipe may be selective with respect to the material of the substrate layers that are subjacent to a metal resist patterning layer. In particular embodiments, the gases may include a combination of inert gas species, hydrogen-containing species, and carbon containing species, suitable for reactive etching a metal resist material such as SnO₂, in a manner that generates volatile metal etch products containing the metallic species of the metal resist, as discussed above.

In the example of FIG. 6B, the angled ion beam 610 is provided as a ribbon ion beam extending to a beam width along the X-direction, where the beam width is adequate to expose an entire width of the substrate 102, even at the widest part along the X-direction. Exemplary beam widths may be in the range of 10 cm, 20 cm, 30 cm, or more while exemplary beam lengths along the Y-direction may be in the range of 3 mm, 5 mm, 10 mm, or 20 mm. The embodiments are not limited in this context.

As also indicated in FIG. 6B, the substrate 102 may be scanned in the scan direction 616, where the scan direction 616 lies in the X-Y plane, such as along the Y-direction. Notably, the scan direction 616 may represent the scanning of substrate 102 in two opposing (180 degrees) directions along the Y-axis, or just a scan toward the left or a scan toward the right. As shown in FIG. 6B, the long axis of angled ion beam 610 extends along the X-direction, perpendicularly to the scan direction 616. Accordingly, an entirety of the substrate 102 may be exposed to the angled ion beam 610 when scanning of the substrate 102 takes place along a scan direction 616 to an adequate length from a left side to right side of substrate 102 as shown in FIG. 6B.

Turning now to FIG. 6C, there is shown another processing apparatus 640, depicted in schematic form. The processing apparatus 640 represents a processing apparatus for performing angled ion treatment of a substrate, and may be substantially the same as the processing apparatus 600, save for the differences discussed below. Notably, the processing apparatus 640 includes a beam blocker 632, disposed adjacent the extraction aperture 608. The beam blocker 532 is sized and positioned to define a first aperture 608A and a second aperture 608B, where the first aperture 608A forms a first beamlet, shown as angled ion beam 610A, and the second aperture 608B forms a second beamlet, shown as angled ion beam 610B. The two angled ion beams may define angles of incidence with respect to the perpendicular 626, equal in magnitude, opposite in direction. In one embodiment, the first angled ion beam 610A may represent beamlet 130A, while the second angled ion beam 610B represents beamlet 130B. The beam blocker offset along the Z-axis with respect to extraction plate 606 may help define the angle of the angled ion beams. As such, the first angled ion beam 610A and the second angled ion beam 610B may treat opposing sidewalls of a device structure simultaneously, as generally depicted in FIG. 1C. When configured in the shape of a ribbon beam as in FIG. 6B, these beamlets may expose an entirety of the substrate 102 to reactive ion etching of metal resist features that are arranged, for example, in arrays distributed across the substrate 102, by scanning the substrate stage 614 as shown. In this configuration opposite sidewalls of the trenches, vias, lines, pillars, and so forth, may be etched simultaneously, thus changing the dimensions of such features in two opposite directions along the Y-axis in one scan operation.

### Experiments

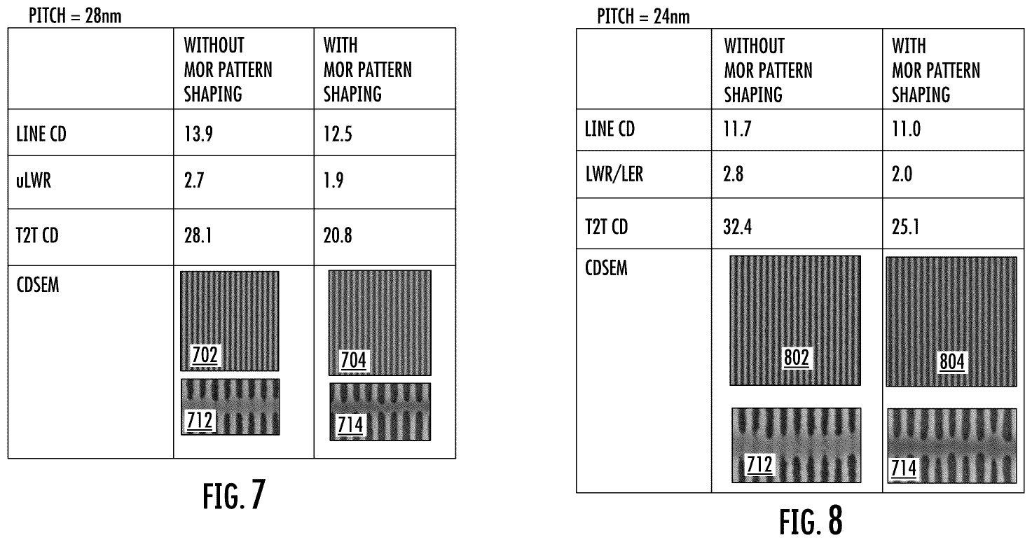

FIG. 7 is a composite illustration including experimental micrographic images of processing an array of patterning features, in accordance with embodiments of the disclosure. In FIG. 7, the results of experimental processing of an array of SnO₂ trenches in accordance with an embodiment of the disclosure are summarized. The array of trenches are arranged as elongated lines, shown as array 702 and array 704. The experimental results are organized into two main columns: the middle column presents measurements of the array of trenches, as well as micrographs, before processing with an angled ion beam (without metal oxide resist pattern shaping); the right column presents measurements for the same array of trenches after processing with an angled ion beam (with metal oxide resist pattern shaping), in accordance with the present embodiments. The middle column thus presents a summary of relevant measurements of an array of trenches after lithographic processing to define the array of trenches in a SnO₂ resist layer, but before angled ion beam etching.

The arrays of trenches shown in FIG. 7 are lithographically processed to define arrays that have nominal 1:1 line: space dimensions, where the pitch is designed to be equal to twice the linewidth. As shown, the pitch (in this case, the horizontal distance between centers of adjacent ‘lines’ shown in array 702 or array 704) for this set of trenches is 28 nm, with a critical dimension (CD) for the trenches of 13.9 nm (horizontal dimension) before angled ion beam etching, and a linewidth roughness (uLWR) of 2.7 nm. Note that an array area 712 is also shown in the middle column, representing an enlarged micrograph image of a portion of the array 702. The array area 712 represents a region of the array 702 where a lower block of trenches (shown as the darker features) is separated from an upper block of trenches. The average vertical distance (in the image as shown in FIG. 7) between the tips of any given adjacent pair of lines for the array area 712 represents the measured tip to tip critical dimension (T2TCD) after lithographic processing, and before angled ion beam etching. In the array area 712, the measured T2TCD is 28.1 nm.

After processing of the array 702 with an angled reactive ion beam that is derived from a plasma including a mixture of Ar and H₂ gases, the line CD (corresponding the metal resist linear features (light lines) between trenches) decreases slightly by just over 1 nm to 12.5 nm, meaning the trenches of the array 702 have been enlarged along the horizontal direction by just over 1 nm. Note that the line width roughness is reduced to 1.9 nm, while the T2TCD is reduced to 20.8 nm, as shown also in the array area 714, corresponding to an enlarged region of the array 704, where adjacent blocks of lines terminate. Thus, the results of FIG. 7 illustrate that, at a pitch or 28 nm, a reactive angled ion beam process is effective to substantially reduce tip-to-tip separation in an array of trenches formed in a SnO₂ metal resist layer, while just slightly enlarging the trench width.

FIG. 8 is a composite illustration including experimental micrographic images of processing another array of patterning features, in accordance with embodiments of the disclosure. In this figure, the results are organized exactly as in FIG. 7, with the sole difference being that the experimental results of FIG. 8 are derived from a set of trenches formed in an SnO₂ layer having a slightly smaller pitch (24 nm) and slightly smaller line CD (11.7 linewidth) as defined after lithographic processing. The measured LWR/EWR after lithographic processing and before angled ion beam treatment is 2.8 nm, while the T2TCD is 32.4 in this case. Note that the value of the T2TCD immediately after lithographic processing is greater in this case as compared to FIG. 7 with the larger pitch (28 nm). Thus, these results demonstrate the increased difficulty of generating small T2T when pitch shrinks, especially at pitch below 40 nm. After processing of the array 802 with an angled reactive ion beam that is derived from a plasma including a mixture of Ar and H₂ gases, the line CD remains nearly unchanged, decreasing slightly to 11.0 nm, meaning the trenches of the array area 714 have been enlarged along the horizontal direction by approximately 0.7 nm. Again the line width roughness has decreased to 2.0 nm, while the T2TCD has decreased substantially to 25.1 nm. Thus, the results of FIG. 7 and FIG. 8 illustrate that a reactive angled ion beam etching procedure is effective to substantially reduce tip-to-tip spacing in arrays of trenches having pitch below 30 nm, and is especially effective to counter the trend toward increasing T2T pitch that results as array pitch shrinks.

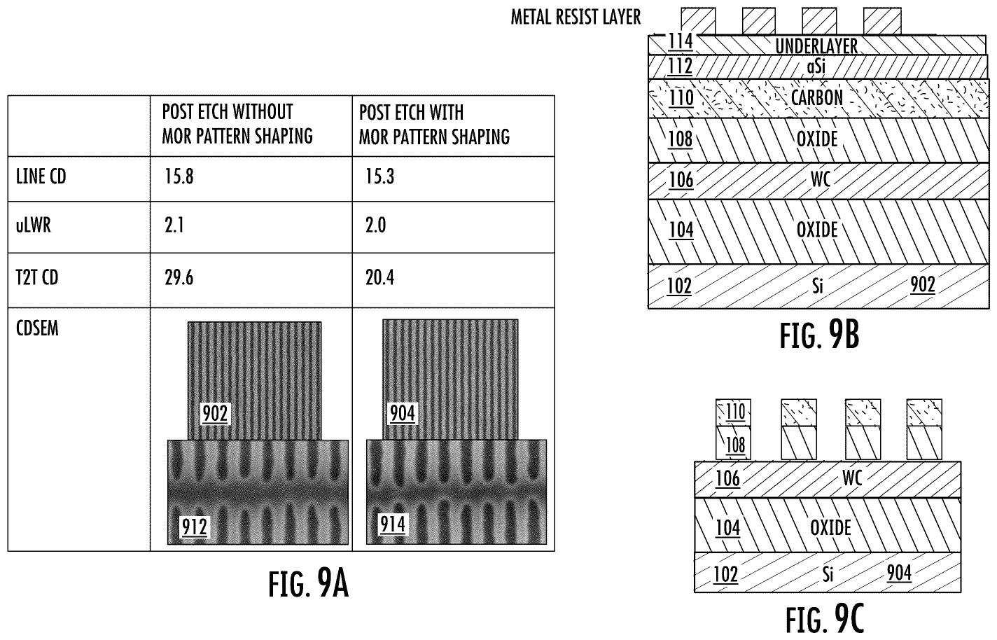

FIG. 9A is a composite illustration including experimental micrographic images of processing a further array of patterning features, showing a comparison of results when angled ion beam etching is omitted after lithography, or is used after lithography, in accordance with embodiments of the disclosure. FIG. 9B and FIG. 9C are side cross-sectional views that depict the general geometry at two different stages of processing of patterning features, applicable to the scenario for processing of FIG. 9A. The results of FIG. 9A are based upon the same type of array as in FIG. 7, with an array of trenches in the shape of elongated lines having a pitch of 28 nm.

A difference in the experimental results presented in FIG. 9A with the results of FIG. 7 are that the results of FIG. 9 are presented after a vertical transfer etch of the underlying substrate has been performed. This process is illustrated by FIG. 9B and FIG. 9C. FIG. 9B presents a cross-sectional illustration of the trench array, representative generally of array 702 or array 704, where the trench array presents an array of trenches formed within a metal resist mask layer. FIG. 9C presents a cross-sectional illustration of the trench array, representative generally of array 902 or array 904, where the trench array presents an array of trenches formed within a layer or set of layers that are subjacent to the metal resist mask layer. In particular, the trenches for array 902 and array 904 may represent trenches formed in a carbon/oxide bilayer, disposed well below the metal resist mask layer. Thus, at the stage of processing represented by the array 902 or array 904, several layers of a layer stack below the original metal resist layer have been etched by a vertical etch process, while the metal resist layer has been removed.

The difference between the results for array 902 and array 904 is that in array 902, no angled ion beam etching is performed after lithography and before vertical etching of the subjacent substrate layers. Again, the array area 912 represents an enlarged view of a portion of the array 902 where adjacent blocks of lines terminate on their ends. As shown in the middle column, without angled ion beam etching, the line CD after the vertical etch layer is 15.8 nm, the uLWR is 2.1 nm, while the T2T CD is 29.6 nm. When angled ion beam etching is performed after lithography and before vertical etching, as shown in array area 914, the line CD does not differ markedly, decreasing just to 15.3 nm (as compared to 15.8 nm without angled ion beam etching), meaning that the trench width in array 904 increases just slightly from 12.2 nm (=28 nm-15.8) to 12.7 nm (=28 nm−15.3 nm). Again, the uLWR is marginally improved with angled ion beam etching, decreasing to 2.0 nm, while the T2T CD dramatically reduces to 20.4 nm. Thus, the results of FIG. 9A show that the advantages of employing reactive angled ion beam etching of arrays of trenches formed in a metal resist layer as an adjunct to lithographic processing are preserved, even after vertical etching to transfer the pattern of the metal resist layer into subjacent substrate layers.

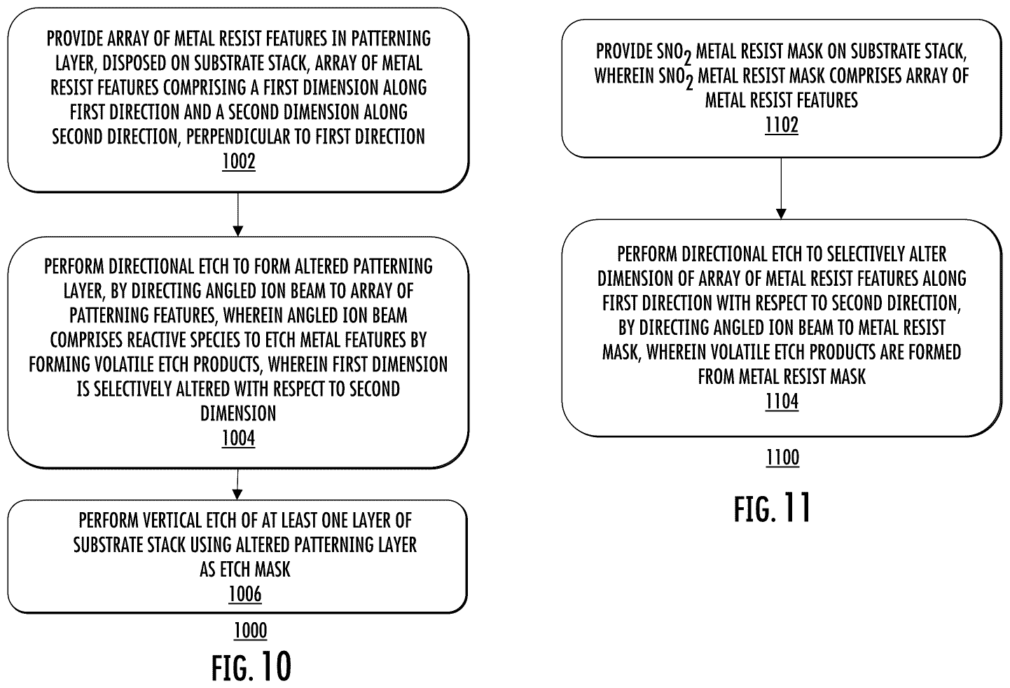

FIG. 10 depicts an exemplary process flow 1000. At block 1002, an array of metal resist features is provided in a patterning layer, disposed on a substrate stack. The array of metal resist features may be an array of features formed in a metal resist layer, such as SnO₂, including an array of lines, array of pillars, an array of trenches, and array of vias, and so forth. The array of metal resist features may be defined by a first dimension along first direction and a second dimension along second direction, perpendicular to first direction.

At block 1004, a directional etch is performed to form an altered patterning layer, by directing an angled ion beam to the array of metal resist features. In particular, the directional etch may be performed using an angled ion beam that includes reactive species to etch metal features by forming volatile etch products, where the first dimension is selectively altered with respect to second dimension. As an example, the angled ion beam may be formed by a set of gas species provided to a plasma chamber that include a combination of inert gas, hydrogen-containing gas, and carbon-containing gas.

At block 1006, after the directional etch, a vertical etch is performed to etch at least one layer of the substrate stack using the altered patterning layer as an etch mask.

FIG. 11 depicts another exemplary process flow 1100. At block 1102, an SnO₂ metal resist mask is provided on a substrate stack, wherein the SnO₂ metal resist mask comprises an array of metal resist features. At block 1104, a directional etch is performed to selectively alter a dimension of array of metal resist features along first direction with respect to second direction, by directing an angled ion beam to the metal resist mask, wherein volatile etch products are formed from the metal resist mask. As such, the metal resist features may be selectively etched to change the dimensions, shape, separation, or other features of the metal resist mask in a manner that does not produce metal contaminants on a substrate or other components in a chamber containing the substrate.

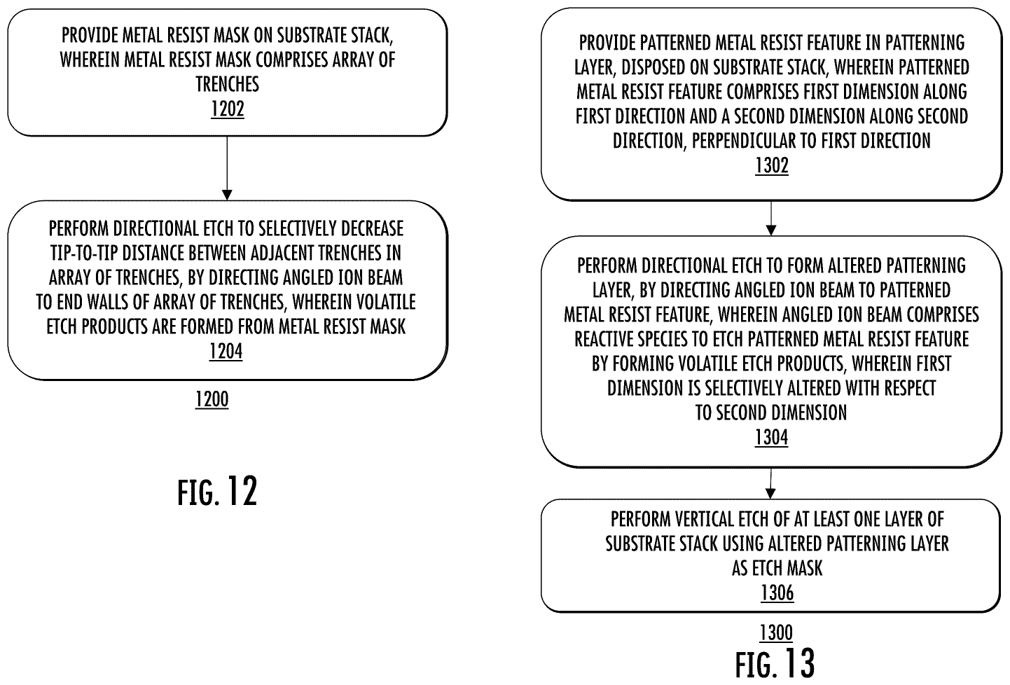

FIG. 12 depicts a further exemplary process flow 1200. At block 1202, a metal resist mask is provided on a substrate stack of a substrate, wherein the metal resist mask comprises an array of trenches. At block 1204, a directional etch is performed to selectively decrease the tip-to-tip distance between adjacent trenches in the array of trenches, by directing and angled ion beam to end walls of the array of trenches. As such, the directional etch may include etching species designed to generate volatile etch products from the metal resist mask, in a manner that prevents contamination of the substrate and components within a processing system where the directional etch is performed.

FIG. 13 depicts yet another exemplary process flow 1300. At block 1302, a patterned metal resist feature is provided in a patterning layer, disposed on a substrate stack of a substrate, wherein the patterned metal resist feature has a first dimension along a first direction and a second dimension along a second direction, perpendicular to first direction. At block 1304, a directional etch is performed to form an altered patterning layer, by directing an angled ion beam to the patterned metal resist feature, wherein the angled ion beam comprises reactive species that are effective to etch the patterned metal resist feature by forming volatile etch products, wherein the first dimension is selectively altered with respect to the second dimension.

At block 1306, after the directional etch, a vertical etch is performed to etch at least one layer of the substrate stack using the altered patterning layer as an etch mask.

The present embodiments provide various advantages over conventional processing to define features in a substrate. One advantage lies in the ability to simplify the process flow for patterning features in a substrate, especially at dimensions below 50 nm. Another advantage is the ability to avoid extra lithography masks, such as extra EUV masks, which masks may otherwise be called for in order to image arrays of features having a small pitch at a designed tip-to-tip spacing. A further advantage is that the pattern shaping for small features is performed at the metal resist layer, so that the process flow is compatible with a re-work process. An additional advantage is that the reactive angled ion beam processing of the present embodiments provides an approach to harness the advantages of using metal resist masks for substrate patterning, while reducing the metal contamination risk by virtue of the ion beam chemistry being designed to generate volatile metal-containing etch products that can be evacuated from a processing system.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, the present disclosure has been described herein in the context of a particular implementation in a particular environment for a particular purpose, while those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of enhancing patterning of a substrate, comprising:
providing a metal resist mask on a substrate stack of the substrate, wherein the metal resist mask comprises at least one patterning feature; and
subjecting the metal resist mask to a directional etch, by directing an angled ion beam to the at least one patterning feature, wherein the angled ion beam comprises reactive species to etch the at least one patterning feature by forming volatile etch products, wherein a first dimension of the at least one patterning feature is selectively altered with respect to a second dimension.

2. The method of claim 1, wherein the metal resist mask comprises SnO₂.

3. The method of claim 1, wherein the at least one patterning feature comprises an array of cavities.

4. The method of claim 3, wherein the array of cavities comprises an array of trenches, wherein a trench length of the array of cavities is increased selectively with respect to a trench width of the array of cavities.

5. The method of claim 4, wherein a tip-to-tip spacing between adjacent trenches of the array of trenches is reduced as a result of the directional etch.

6. The method of claim 1, wherein the metal resist mask extends along a main plane of the substrate, wherein the angled ion beam defines a trajectory that is arranged at a non-zero angle with respect to a perpendicular to the main plane.

7. The method of claim 1, wherein the angled ion beam is generated from a set of species that are generated in a plasma chamber, wherein the set of species comprises at least one inert gas, and further comprises at least one hydrogen-containing gas.

8. The method of claim 7, wherein the set of species further comprises at least one carbon-containing gas.

9. The method of claim 7, wherein the angled ion beam comprises a pair of ion beamlets.

10. The method of claim 9, wherein the hydrogen-containing gas comprises at least one of: include CH₄, CₓH_{y}, CₓH_{y}OH, HCl, and HBr.

11. An apparatus to etch a substrate having a metal mask, comprising:
a plasma chamber to generate a plasma therein;
a process chamber, adjacent to the plasma chamber, to house the substrate;
an extraction plate, disposed between the plasma chamber and the substrate, and having an extraction aperture to generate and direct an angled ion beam to the substrate; and
a gas source, to provide a gas mixture to the plasma chamber to form the plasma,
wherein the gas mixture includes at least one hydrogen-containing gas, at least one carbon-containing gas, and at least one inert gas,
wherein the at least one hydrogen-containing gas comprises at least one of: include CH₄, CₓH_{y}, CₓH_{y}OH, HCl, and HBr.

12. The apparatus of claim 11, wherein the extraction aperture is elongated along a first direction, wherein the angled ion beam is formed as a ribbon beam that is elongated along the first direction.

13. The apparatus of claim 11, further comprising a beam blocker, disposed adjacent to the extraction aperture, wherein the beam blocker is sized and positioned to partition the extraction aperture into a first aperture and a second aperture, where the first aperture forms a first beamlet, and the second aperture forms a second beamlet.

14. The apparatus of claim 13, wherein the first beamlet and the second beamlet define a first angle of incidence with respect to a perpendicular to a plane of the substrate, and a second angle of incidence with respect to the perpendicular, the first angle of incidence and the second angle of incidence being equal in magnitude, and opposite in direction.

15. The apparatus of claim 11, wherein the angled ion beam includes a combination of ions and radicals are extracted through the extraction aperture, and impinge upon the substrate.

16. The apparatus of claim 15, wherein the radicals include hydrogen radicals that are configured to react with metal material of the metal mask, and to form a volatile metal etch product based upon the metal material.

17. The apparatus of claim 15, wherein the metal mask comprises a set of patterning features having a set of sidewalls and a set of top surfaces, respectively, and wherein the combination of ions and radicals is configured to generate a carbon-containing deposit that forms on the top surfaces, and wherein the combination of ions and radicals is configured to etch the sidewalls.

18. A method of enhancing patterning of a substrate, comprising:
providing a SnO₂ resist mask on a substrate stack of the substrate, wherein the SnO₂ resist mask comprises at least one patterning feature;
forming a plasma in a plasma chamber using a gas mixture comprising an inert gas and at least one of: CH₄, CₓH_{y}, CₓH_{y}OH, HCl, and HBr;
extracting an angled ion beam from the plasma chamber and directing the angled ion beam to the at least one patterning feature, and
wherein the angled ion beam comprises reactive species to etch the at least one patterning feature by forming volatile etch products, wherein a first dimension of the at least one patterning feature is selectively altered with respect to second dimension, and wherein a protective layer forms on a top surface of the at least one patterning feature.

19. The method of claim 18, wherein the angled ion beam comprises a pair of ion beamlets that are directed to opposite sides of the at least one patterning feature.
